(19) United States
(12) Patent Application Publication
(10) Pub. No.: US 2023/0161430 A1
(43) Pub. Date: May 25, 2023

(54) LED TOUCH CHIP AND MANUFACTURING METHOD THEREOF, AND DISPLAY DEVICE

(71) Applicant: CHONGQING KONKA PHOTOELECTRIC TECHNOLOGY RESEARCH INSTITUTE CO., LTD., Chongqing (CN)

(72) Inventors: Erlong QI, Chongqing (CN); Peng LIU, Chongqing (CN)

(21) Appl. No.: 18/152,890

(22) Filed: Jan. 11, 2023

Related U.S. Application Data
(63) Continuation of application No. PCT/CN2021/133721, filed on Nov. 26, 2021.

(30) Foreign Application Priority Data
Mar. 10, 2021 (CN) 202110260609.2

(51) Int. Cl. G06F 3/041; G06F 3/044; H01L 33/00; H01L 33/06; H01L 33/38; H01L 33/46

(52) U.S. Cl. CPC G06F 3/0412; G06F 3/0445; H01L 33/0075; H01L 33/06; H01L 33/382; H01L 33/46; G06F 2203/04103; H01L 2933/0016; H01L 2933/0025

(57) ABSTRACT

A light-emitting diode (LED) touch chip and a manufacturing method thereof, and a display device are provided. The LED touch chip includes a base substrate, a touch-screen structure, and an LED-lamp-bead structure. The touch-screen structure is disposed on the base substrate, and configured to provide a touch function for the LED touch chip. The LED-lamp-bead structure is disposed in the touch-screen structure, and configured to provide a light-emitting display function. The touch-screen structure defines a receiving cavity, and the LED-lamp-bead structure is disposed in the receiving cavity and exposed from the receiving cavity to emit lights.

### CROSS-REFERENCE TO RELATED APPLICATION(S)

This application is a continuation of International Application No. PCT/CN2021/133721, filed Nov. 26, 2021, which claims priority to Chinese Patent Application No. 202110260609.2, filed on Mar. 10, 2021, the disclosures of which are hereby incorporated by reference in their entireties.

### TECHNICAL FIELD

This application relates to the field of display technologies, and particularly to a light-emitting diode (LED) touch chip, a method for manufacturing the LED touch chip, and a display device having the LED touch chip.

### BACKGROUND

At present, light-emitting diodes (LED) have been widely used in the display field because of their advantages of high brightness, low power consumption, long service life, energy saving and environmental protection, etc. With continuous development of display technologies, a resolution of an image becomes higher and higher, and a dot pitch of an LED screen becomes smaller and smaller, thus Mini LED and Micro LED technologies have emerged. Mini LEDs and Micro LEDs are more competitive in a high-end display industry because of their high brightness, wide color gamut, fast refresh rate, and other advantages. For example, Mini LEDs and Micro LEDs can be used in display devices such as conference all-in-one machines and billboards. Generally, such display device needs to have a touch function in practical application, and adopts an infrared touch screen fixed on a frame of an LED display screen, where the infrared touch screen is configured to detect and locate a user's touch gesture by means of infrared matrices in X and Y directions.

However, using the above infrared touch screen to realize a touch function may cause problems such as a poor sensitivity, delay in operations, prone to be affected by external lights, and lack of anti-interference to strong lights. Moreover, the infrared touch screen, as a single module, generally needs to be fixed on the LED display screen through multiple auxiliary fixing parts, which increases structure complexity, size of the whole display device, and cost.

### SUMMARY

The disclosure provides a light-emitting diode (LED) touch chip. The LED touch chip includes a base substrate, a touch-screen structure, and an LED-lamp-bead structure. The touch-screen structure is disposed on the base substrate, and configured to provide a touch function for the LED touch chip. The LED-lamp-bead structure is disposed in the touch-screen structure, and configured to provide a light-emitting display function. The touch-screen structure defines a receiving cavity. The LED-lamp-bead structure is disposed in the receiving cavity and exposed from the receiving cavity to emit lights.

The disclosure further provides a display device. The display device includes an LED touch chip and a display panel. The LED touch chip is electrically coupled with the display panel. The LED touch chip includes a base substrate, a touch-screen structure, and an LED-lamp-bead structure. The touch-screen structure is disposed on the base substrate, and configured to provide a touch function for the LED touch chip. The LED-lamp-bead structure is disposed in the touch-screen structure, and configured to provide a light-emitting display function. The touch-screen structure defines a receiving cavity. The LED-lamp-bead structure is disposed in the receiving cavity and exposed from the receiving cavity to emit lights.

The disclosure further provides a method for manufacturing an LED touch chip. The method includes the following. A base substrate is provided. An electrode layer is grown on the base substrate. A light-emitting layer is grown on the electrode layer. A fourth electrode layer, a fifth insulating layer, and a fourth insulating layer are grown on the light-emitting layer in sequence. A first touch electrode, a second touch electrode, a first LED-lamp-bead electrode, and a second LED-lamp-bead electrode are manufactured simultaneously, where the first touch electrode is electrically coupled with a first electrode layer, the second touch electrode is electrically coupled with a second electrode layer, the first LED-lamp-bead electrode is electrically coupled with a second semiconductor layer, and the second LED-lamp-bead electrode is electrically coupled with a first semiconductor layer.

### BRIEF DESCRIPTION OF THE DRAWINGS

FIG. 1 is a schematic structural diagram illustrating a light-emitting diode (LED) touch chip provided in implementations of the disclosure.

FIG. 2 is a detailed schematic structural diagram illustrating the LED touch chip illustrated in FIG. 1.

FIG. 3 illustrates a top view of an LED touch chip provided in implementations of the disclosure.

FIG. 4 is a schematic flowchart illustrating a method for manufacturing an LED touch chip provided in implementations of the disclosure.

FIG. 5 is a schematic diagram illustrating a structure formed by performing operations at S20 of the method illustrated in FIG. 4.

FIG. 6 is a schematic flowchart illustrating the operations at S20 of the method illustrated in FIG. 4.

FIG. 7 is a schematic diagram illustrating a structure formed by performing operations at S30 of the method illustrated in FIG. 4.

FIG. 8 is a schematic flowchart illustrating the operations at S30 of the method illustrated in FIG. 4.

FIG. 9 is a schematic diagram illustrating a structure formed by performing operations at S40 of the method illustrated in FIG. 4.

FIG. 10 is a schematic flowchart illustrating the operations at S40 of the method illustrated in FIG. 4.

Reference signs: 100—LED touch chip; 110—touch-screen structure; 120—LED-lamp-bead structure; 1102—receiving cavity; 111—first electrode layer; 112—first insulating layer; 113—second electrode layer; 114—second insulating layer 115—third electrode layer; 116—third insulating layer; 117—fourth insulating layer; 118—first touch electrode; 119—second touch electrode; 121—first semiconductor layer; 122—multi-quantum well light-emitting layer; 123—second semiconductor layer; 124—fourth electrode layer; 125—fifth insulating layer; 126—first LED-lamp-bead electrode; 127—second LED-lamp-bead electrode; 130—touch capacitance region; 10—base substrate; 20—electrode layer; 30—light-emitting layer; S10-S50—operations of a method for manufacturing the LED touch chip; S21-S26—operations of a method for manufacturing the electrode layer; S31-S33—operations of a method for manufacturing the light-emitting layer; S41-S43—operations of a method for manufacturing the fourth electrode layer, the fifth insulating layer, and the fourth insulating layer.

### DETAILED DESCRIPTION

In order to facilitate understanding of the disclosure, the disclosure will be described fully below with reference to accompanying drawings. The accompanying drawings illustrate exemplary implementations of the disclosure. However, the disclosure may be implemented in different forms and is not limited to the implementations described herein. Rather, these implementations are provided to achieve a thorough and complete understanding of disclosed contents of the disclosure.

Unless otherwise defined, all technical and scientific terms herein have the same meaning as commonly understood by one of ordinary skill in the technical field to which the disclosure belongs. The terms used in the specification of the disclosure are merely for the purpose of describing implementations of the disclosure, which are not intended to limit the disclosure.

With continuous development of display technologies, a resolution of an image becomes higher and higher, and a dot pitch of a light-emitting diodes (LED) screen becomes smaller and smaller, thus Mini LED and Micro LED technologies have emerged. Mini LEDs and Micro LEDs are more competitive in a high-end display industry because of their high brightness, wide color gamut, fast refresh rate, and other advantages. For example, Mini LEDs and Micro LEDs can be used in display devices such as conference all-in-one machines and billboards. Generally, such display device needs to have a touch function in practical application, and adopts an infrared touch screen fixed on a frame of an LED display screen, where the infrared touch screen is configured to detect and locate a user's touch gesture by means of infrared matrices in X and Y directions. However, using the above infrared touch screen to realize a touch function may cause problems such as a poor sensitivity, delay in operations, prone to be affected by external lights, and lack of anti-interference to strong lights. Moreover, the infrared touch screen, as a single module, generally needs to be fixed on the LED display screen through multiple auxiliary fixing parts, which increases structure complexity, size of the whole display device, and cost. Therefore, how to improve the sensitivity of the LED touch screen, reduce the delay in operations, realize a light and thin box-housing, and avoid interferences of external lights and strong lights on the LED display screen have become problems to-be-solved.

Based on the above, the disclosure provides a solution capable of solving the above technical problems, which can solve the problems such as a poor sensitivity of the LED touch screen, delay in operations, prone to be affected by external lights, lack of anti-interference to strong lights, a complex product structure, and a large overall size. The details of the solution will be depicted in the following implementations.

The solution of the disclosure will depict an LED touch chip, a method for manufacturing the LED touch chip, and a display device in detail.

The disclosure provides an LED touch chip. The LED touch chip includes a base substrate, a touch-screen structure, and an LED-lamp-bead structure. The touch-screen structure is disposed on the base substrate, and configured to provide a touch function for the LED touch chip. The LED-lamp-bead structure is disposed in the touch-screen structure, and configured to provide a light-emitting display function. The touch-screen structure defines a receiving cavity. The LED-lamp-bead structure is disposed in the receiving cavity and exposed from the receiving cavity to emit lights.

The above LED touch chip can improve the sensitivity of the touch screen, reduce the cost of the touch screen, reduce a thickness of an outer frame of the touch screen, and improve an anti-interference performance of the touch screen.

In some implementations, the touch-screen structure includes a first electrode layer, a first insulating layer, a second electrode layer, a second insulating layer, a third electrode layer, a third insulating layer, and a fourth insulating layer. The first electrode layer is disposed on the base substrate. The first insulating layer is disposed on the first electrode layer and the base substrate. The second electrode layer is disposed on the first insulating layer. The second insulating layer is disposed on the second electrode layer and the first insulating layer. The third electrode layer is disposed on the second insulating layer. Part of the third insulating layer is disposed on the third electrode layer, and the rest of the third insulating layer is disposed on the second insulating layer. The fourth insulating layer is disposed on the third insulating layer, where the receiving cavity is defined in the fourth insulating layer.

In some implementations, the touch-screen structure further includes a first touch electrode and a second touch electrode. The first touch electrode extends through the fourth insulating layer, the third insulating layer, the second insulating layer, and the first insulating layer in sequence, and is electrically coupled with the first electrode layer. The second touch electrode extends through the fourth insulating layer, the third insulating layer, and the second insulating layer in sequence, and is electrically coupled with the second electrode layer.

In some implementations, the LED-lamp-bead structure includes a first semiconductor layer, a multi-quantum well light-emitting layer, a second semiconductor layer, a fourth electrode layer, and a fifth insulating layer. The first semiconductor layer is disposed on the third insulating layer. The multi-quantum well light-emitting layer is disposed on the first semiconductor layer. The second semiconductor layer is disposed on the multi-quantum well light-emitting layer. The fourth electrode layer is disposed on the second semiconductor layer. The fifth insulating layer is disposed on the fourth electrode layer and the second semiconductor layer.

In some implementations, the LED-lamp-bead structure further includes a first LED-lamp-bead electrode and a second LED-lamp-bead electrode. The first LED-lamp-bead electrode extends through the fifth insulating layer and the fourth electrode layer in sequence, and is electrically coupled with the second semiconductor layer. The second LED-lamp-bead electrode is spaced apart from the first LED-lamp-bead electrode, extends through the fifth insulating layer, the fourth electrode layer, the second semiconductor layer, and the multi-quantum well light-emitting layer in sequence, and is electrically coupled with the first semiconductor layer.

In some implementations, the first electrode layer and the second electrode layer each are made of indium tin oxide. The first insulating layer, the second insulating layer, and the third insulating layer each are made of a transparent and non-conductive material. The first touch electrode and the second touch electrode each are made of a conductive material.

In some implementations, the third electrode layer is not coupled with other electrodes.

In some implementations, the fourth insulating layer and the fifth insulating layer each are a distributed Bragg reflector (DBR). The first semiconductor layer is made of an N-type semiconductor material. The second semiconductor layer is made of a P-type semiconductor material.

In some implementations, the fourth insulating layer and the fifth insulating layer each are a DBR. The first semiconductor layer is made of a P-type semiconductor material. The second semiconductor layer is made of an N-type semiconductor material.

By adopting the above LED touch chip, the problems such as a poor sensitivity of the LED touch screen, delay in operations, prone to be affected by external lights, lack of anti-interference to strong lights, a complex product structure, and a large overall size can be solved, thereby improving the sensitivity of the touch screen, reducing the cost of the touch screen, reducing a thickness of an outer frame of the touch screen, and improving an anti-interference performance of the touch screen.

Based on the same inventive concept, the disclosure further provides a display device. The display device includes an LED touch chip and a display panel. The LED touch chip is electrically coupled with the display panel. The LED touch chip includes a base substrate, a touch-screen structure, and an LED-lamp-bead structure. The touch-screen structure is disposed on the base substrate, and configured to provide a touch function for the LED touch chip. The LED-lamp-bead structure is disposed in the touch-screen structure, and configured to provide a light-emitting display function. The touch-screen structure defines a receiving cavity. The LED-lamp-bead structure is disposed in the receiving cavity and exposed from the receiving cavity to emit lights.

In the above display device, the LED touch chip of the display device can improve the sensitivity of the touch screen, reduce the cost of the touch screen, reduce a thickness of an outer frame of the touch screen, and improve an anti-interference performance of the touch screen.

In some implementations, the touch-screen structure includes a first electrode layer, a first insulating layer, a second electrode layer, a second insulating layer, a third electrode layer, a third insulating layer, and a fourth insulating layer. The first electrode layer is disposed on the base substrate. The first insulating layer is disposed on the first electrode layer and the base substrate. The second electrode layer is disposed on the first insulating layer. The second insulating layer is disposed on the second electrode layer and the first insulating layer. The third electrode layer is disposed on the second insulating layer. Part of the third insulating layer is disposed on the third electrode layer, and the rest of the third insulating layer is disposed on the second insulating layer. The fourth insulating layer is disposed on the third insulating layer, where the receiving cavity is defined in the fourth insulating layer.

In some implementations, the touch-screen structure further includes a first touch electrode and a second touch electrode. The first touch electrode extends through the fourth insulating layer, the third insulating layer, the second insulating layer, and the first insulating layer in sequence, and is electrically coupled with the first electrode layer. The second touch electrode extends through the fourth insulating layer, the third insulating layer, and the second insulating layer in sequence, and is electrically coupled with the second electrode layer.

In some implementations, the LED-lamp-bead structure includes a first semiconductor layer, a multi-quantum well light-emitting layer, a second semiconductor layer, a fourth electrode layer, and a fifth insulating layer. The first semiconductor layer is disposed on the third insulating layer. The multi-quantum well light-emitting layer is disposed on the first semiconductor layer. The second semiconductor layer is disposed on the multi-quantum well light-emitting layer. The fourth electrode layer is disposed on the second semiconductor layer. The fifth insulating layer is disposed on the fourth electrode layer and the second semiconductor layer.

In some implementations, the LED-lamp-bead structure further includes a first LED-lamp-bead electrode and a second LED-lamp-bead electrode. The first LED-lamp-bead electrode extends through the fifth insulating layer and the fourth electrode layer in sequence, and is electrically coupled with the second semiconductor layer. The second LED-lamp-bead electrode is spaced apart from the first LED-lamp-bead electrode, extends through the fifth insulating layer, the fourth electrode layer, the second semiconductor layer, and the multi-quantum well light-emitting layer in sequence, and is electrically coupled with the first semiconductor layer.

In some implementations, the third electrode layer is not coupled with other electrodes.

In the above display device, the LED touch chip of the display device can improve the sensitivity of the touch screen, reduce the cost of the touch screen, reduce a thickness of an outer frame of the touch screen, and improve an anti-interference performance of the touch screen.

Based on the same inventive concept, the disclosure further provides a method for manufacturing an LED touch chip. The method includes the following. A base substrate is provided. An electrode layer is grown on the base substrate. A light-emitting layer is grown on the electrode layer. A fourth electrode layer, a fifth insulating layer, and a fourth insulating layer are grown on the light-emitting layer in sequence. A first touch electrode, a second touch electrode, a first LED-lamp-bead electrode, and a second LED-lamp-bead electrode are manufactured simultaneously, where the first touch electrode is electrically coupled with a first electrode layer, the second touch electrode is electrically coupled with a second electrode layer, the first LED-lamp-bead electrode is electrically coupled with a second semiconductor layer, and the second LED-lamp-bead electrode is electrically coupled with a first semiconductor layer.

The LED touch chip manufactured with the method for manufacturing the LED touch chip can solve the problems such as a poor sensitivity of the LED touch screen, delay in operations, prone to be affected by external lights, lack of anti-interference to strong lights, a complex product structure, and a large overall size, thereby improving the sensitivity of the touch screen, reducing the cost of the touch screen, reducing a thickness of an outer frame of the touch screen, and improving an anti-interference performance of the touch screen.

In some implementations, the electrode layer is grown on the base substrate as follows. The first electrode layer is grown on the base substrate. A first insulating layer is grown on the first electrode layer and the base substrate. The second electrode layer is grown on the first insulating layer. A second insulating layer is grown on the second electrode layer and the first insulating layer. A third electrode layer is grown on the second insulating layer. A third insulating layer is grown on the third electrode layer and the second insulating layer.

In some implementations, the light-emitting layer is grown on the electrode layer as follows. The first semiconductor layer is grown on the third insulating layer. A multi-quantum well light-emitting layer is grown on the first semiconductor layer. The second semiconductor layer is grown on the multi-quantum well light-emitting layer.

In some implementations, the fourth electrode layer, the fifth insulating layer, and the fourth insulating layer are grown on the light-emitting layer in sequence as follows. The fourth electrode layer is grown on the second semiconductor layer. The fifth insulating layer is grown on the fourth electrode layer and the second semiconductor layer. The fourth insulating layer is grown on the third insulating layer, where inner walls of the fourth insulating layer and the third insulating layer cooperatively define a receiving cavity, and the light-emitting layer, the fourth electrode layer, the fifth insulating layer, the first LED-lamp-bead electrode, and the second LED-lamp-bead electrode are disposed in the receiving cavity.

In some implementations, the first electrode layer, the second electrode layer, and the third electrode layer each are generated through physical vapor deposition (PVD) ion plating. The first insulating layer, the second insulating layer, and the third insulating layer each are generated through chemical vapor deposition (CVD).

Referring to FIG. 1, FIG. 1 is a schematic structural diagram illustrating an LED touch chip provided in implementations of the disclosure. As illustrated in FIG. 1, the disclosure provides an LED touch chip 100. The LED touch chip 100 includes a base substrate (not illustrated), a touch-screen structure 110, and an LED-lamp-bead structure 120. The touch-screen structure 110 is disposed on the base substrate, and configured to provide a touch function for the LED touch chip 100. The LED-lamp-bead structure 120 is disposed in the touch-screen structure 110 and exposed from the touch-screen structure 110, and configured to provide a light-emitting display function. Specifically, the touch-screen structure 110 defines a receiving cavity 1102. The receiving cavity 1102 match the LED-lamp-bead structure 120 in size and shape. The LED-lamp-bead structure 120 is disposed in the receiving cavity 1102. Side and bottom surfaces of the LED-lamp-bead structure 120 are in contact with the receiving cavity 1102. The LED-lamp-bead structure 120 is exposed from the receiving cavity 1102 to emit required lights.

In implementations of the disclosure, the LED-lamp-bead structure 120 may be a flip-chip LED-lamp-bead structure.

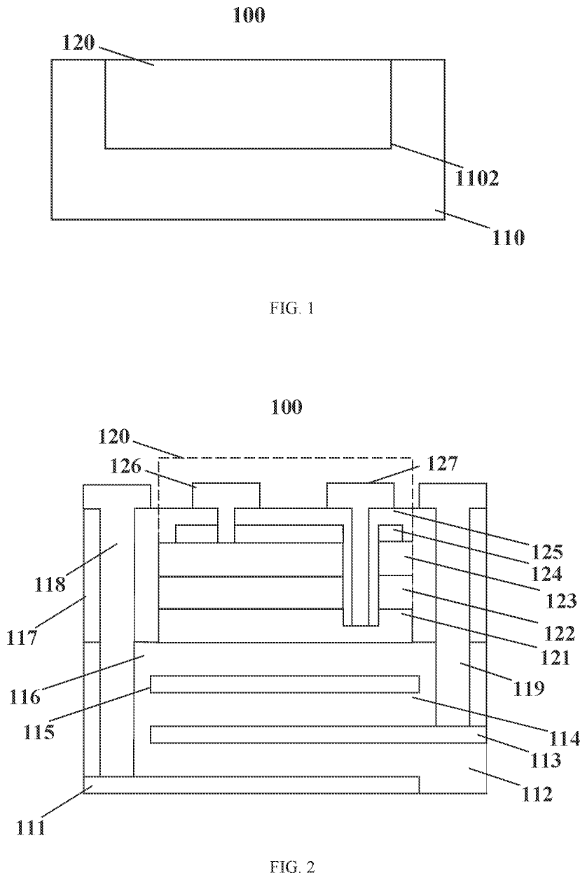

Referring to FIG. 2, FIG. 2 is a detailed schematic structural diagram illustrating the LED touch chip illustrated in FIG. 1. As illustrated in FIG. 2, the touch-screen structure 110 includes a first electrode layer 111, a first insulating layer 112, a second electrode insulating layer 113, a second insulating layer 114, a third electrode layer 115, a third insulating layer 116, a fourth insulating layer 117, a first touch electrode 118, and a second touch electrode 119.

The first electrode layer 111 is disposed on the base substrate, and coupled with a substrate electrode (not illustrated) through the first touch electrode 118. The coupling includes solder-paste bonding. In implementations of the disclosure, the first electrode layer 111 may be made of indium tin oxide, and has good transparency and conductivity.

In some implementations, the first electrode layer 111 is disposed on the base substrate, and the first insulating layer 112 is disposed on a surface of the first electrode layer 111 away from the base substrate. In other implementations, part of the first insulating layer 112 is disposed on the first electrode layer 111, and the rest of the first insulating layer 112 is disposed on the base substrate. That is, both the first electrode layer 111 and the first insulating layer 112 are disposed on the base substrate. In implementations of the disclosure, the first insulating layer 112 may be made of a transparent and non-conductive material, such as resin.

The second electrode layer 113 is disposed on the first insulating layer 112, that is, the first insulating layer 112 is disposed between the first electrode layer 111 and the second electrode layer 113, to isolate the first electrode layer 111 from the second electrode layer 113, so that the first electrode layer 111 and the second electrode layer 113 are not conductive with each other.

In implementations of the disclosure, the second electrode layer 113 may be made of indium tin oxide, and has good transparency and conductivity.

Part of the second insulating layer 114 is disposed on the second electrode layer 113, and the rest of the second insulating layer 114 is disposed on the first insulating layer 112. The third electrode layer 115 is disposed on the second insulating layer 114. That is, the second insulating layer 114 is disposed between the second electrode layer 113 and the third electrode layer 115, to isolate the second electrode layer 113 from the third electrode layer 115, so that the second electrode layer 113 and the third electrode layer 115 are not conductive with each other.

In implementations of the disclosure, the second insulating layer 114 may be made of a transparent and non-conductive material, such as resin.

The third electrode layer 115 is disposed on the second insulating layer 114, to shield a signal influence of the second electrode layer 113 on a first semiconductor layer 121 in the LED-lamp-bead structure 120. In implementations of the disclosure, the third electrode layer 115 is in a suspended state, that is, the third electrode layer 115 is not coupled with other electrodes.

Part of the third insulating layer 116 is disposed on the third electrode layer 115, and the rest of the third insulating layer 116 is disposed on the second insulating layer 114, that is, the third insulating layer 116 encloses the third electrode layer 115, to isolate the third electrode layer 115 from the first semiconductor layer 121, so that the third electrode layer 115 and the first semiconductor layer 121 are not conductive with each other.

In implementations of the disclosure, the third insulating layer 116 may be made of a transparent and non-conductive material, such as resin.

The fourth insulating layer 117 is disposed on the third insulating layer 116, and defines the receiving cavity 1102. That is, the fourth insulating layer 117 is disposed in an edge region on the third insulating layer 116, a periphery of the fourth insulating layer 117 is aligned with a periphery of the third insulating layer 116, and the fourth insulating layer 117 is disposed around the LED-lamp-bead structure 120. In other words, inner walls of the fourth insulating layer 117 and the third insulating layer 116 cooperatively define the receiving cavity 1102, the LED-lamp-bead structure 120 is disposed on the third insulating layer 116, and the fourth insulating layer 117 is disposed around the LED-lamp-bead structure 120. That is, the LED-lamp-bead structure 120 is disposed in the receiving cavity 1102.

In implementations of the disclosure, the fourth insulating layer 125 may be a distributed Bragg reflector (DBR).

The first touch electrode 118 extends through the fourth insulating layer 117, the third insulating layer 116, the second insulating layer 114, and the first insulating layer 112 in sequence, and is electrically coupled with the first electrode layer 111. The first touch electrode 118 is further electrically coupled with the substrate electrode. That is, the first touch electrode 118 is used to electrically connect the first electrode layer 111 and the substrate electrode. In implementations of the disclosure, the first touch electrode 118 may be made of a material with good electrical conductivity. The coupling between the first touch electrode 118 and the substrate electrode includes solder-paste bonding.

The second touch electrode 119 extends through the fourth insulating layer 117, the third insulating layer 116, and the second insulating layer 114 in sequence, and is electrically coupled with the second electrode layer 113. The second touch electrode 119 is further electrically coupled with the substrate electrode. That is, the second touch electrode 119 is used to electrically connect the second electrode layer 113 and the substrate electrode. In implementations of the disclosure, the second touch electrode 119 may be made of a material with good electrical conductivity. The coupling between the second touch electrode 119 and the substrate electrode includes solder-paste bonding.

An exemplary structure of the touch-screen structure 110 is illustrated above. In some implementations, the touch-screen structure 110 includes the first electrode layer 111, the first insulating layer 112, the second electrode layer 113, the second insulating layer 114, and the fourth insulating layer 117. The first electrode layer 111 is disposed on the base substrate. The first insulating layer 112 is disposed on the first electrode layer 111. The second electrode layer 113 is disposed on the first insulating layer 112. The second insulating layer 114 is disposed on the second electrode layer 113 and the first insulating layer 112. The fourth insulating layer 117 is disposed on the second insulating layer 114, where the fourth insulating layer 117 defines the receiving cavity 1102.

In some implementations, the touch-screen structure 110 further includes the first touch electrode 118 and the second touch electrode 119. The first touch electrode 118 extends through the fourth insulating layer 117, the second insulating layer 114, and the first insulating layer 112 in sequence, and is electrically coupled with the first electrode layer 111. The second touch electrode 119 extends through the fourth insulating layer 117 and the second insulating layer 114 in sequence, and is electrically coupled with the second electrode layer 113.

In some implementations, the touch-screen structure 110 further includes a third electrode layer 115 and a third insulating layer 116 which are disposed between the second insulating layer 114 and the fourth insulating layer 117. The third electrode layer 115 is disposed on the second insulating layer 114. Part of the third insulating layer 116 is disposed on the third electrode layer 115, and the rest of the third insulating layer 116 is disposed on the second insulating layer 114. The fourth insulating layer 117 is disposed on the third insulating layer 116.

In some implementations, the first touch electrode 118 extends through the fourth insulating layer 117, the third insulating layer 116, the second insulating layer 114, and the first insulating layer 112 in sequence, and is electrically coupled with the first electrode layer 111. The second touch electrode 119 extends through the fourth insulating layer 117, the third insulating layer 116, and the second insulating layer 114 in sequence, and is electrically coupled with the second electrode layer 113.

In implementations of the disclosure, the LED-lamp-bead structure 120 includes a first semiconductor layer 121, a multi-quantum well light-emitting layer 122, a second semiconductor layer 123, a fourth electrode layer 124, a fifth insulating layer 125, a first LED-lamp-bead electrode 126, and a second LED-lamp-bead electrode 127.

The first semiconductor layer 121 is disposed on the third insulating layer 116, and configured to provide electrons to recombine with holes provided by the second semiconductor layer 123 to generate photons. In implementations of the disclosure, the first semiconductor layer 121 may be made of an N-type semiconductor material, for example, N-type gallium nitride (GaN).

The multi-quantum well light-emitting layer 122 is disposed on the first semiconductor layer 121, and configured to provide a place where electrons provided by the first semiconductor layer 121 recombine with holes provided by the second semiconductor layer 123 to generate photons.

The second semiconductor layer 123 is disposed on the multi-quantum well light-emitting layer 122, and configured to provide holes to recombine with electrons provided by the first semiconductor layer 121 to generate photons. In implementations of the disclosure, the second semiconductor layer 123 may be made of a P-type semiconductor material, for example, P-type gallium nitride (GaN).

The fourth electrode layer 124 is disposed on the second semiconductor layer 123, and configured to disperse an electric field, so that the electric field of the second semiconductor layer 123 is more uniform and a luminous efficiency is higher.

Part of the fifth insulating layer 125 is disposed on the fourth electrode layer 124, and the rest of the fifth insulating layer 125 is disposed on the second semiconductor layer 123, that is, the fifth insulating layer 125 enclose the fourth electrode layer 124. The fifth insulating layer 125 is used to prevent mutual conduction between electrodes. In implementations of the disclosure, the fifth insulating layer 125 may be a DBR. It can be understood that, in an actual manufacturing process, the fourth insulating layer 117 and the fifth insulating layer 125 may be manufactured at the same time, and manufactured integrally. In implementations of the disclosure, for convenience of description, the fourth insulating layer 117 and the fifth insulating layer 125 are referred to as different insulating layers according to their different positions.

The first LED-lamp-bead electrode 126 extends through the fifth insulating layer 125 and the fourth electrode layer 124 in sequence, and is electrically coupled with the second semiconductor layer 123. The first LED-lamp-bead electrode 126 is further electrically coupled with the substrate electrode. That is, the first LED-lamp-bead electrode 126 is used to electrically connect the second semiconductor layer 123 and the substrate electrode.

The second LED-lamp-bead electrode 127 is spaced apart from the first LED-lamp-bead electrode 126, extends through the fifth insulating layer 125, the fourth electrode layer 124, the second semiconductor layer 123, and the multi-quantum well light-emitting layer 122 in sequence, and is electrically coupled with the first semiconductor layer 121. The second LED-lamp-bead electrode 127 is further electrically coupled with the substrate electrode. That is, the second LED-lamp-bead electrode 127 is used to electrically connect the first semiconductor layer 121 and the substrate electrode.

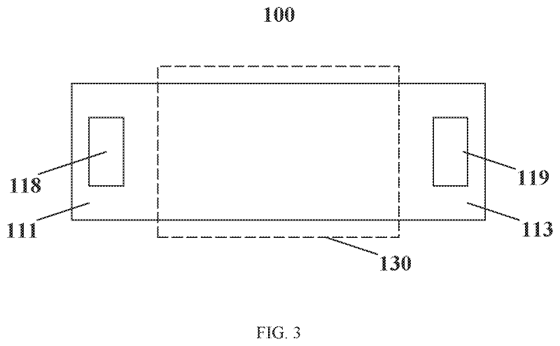

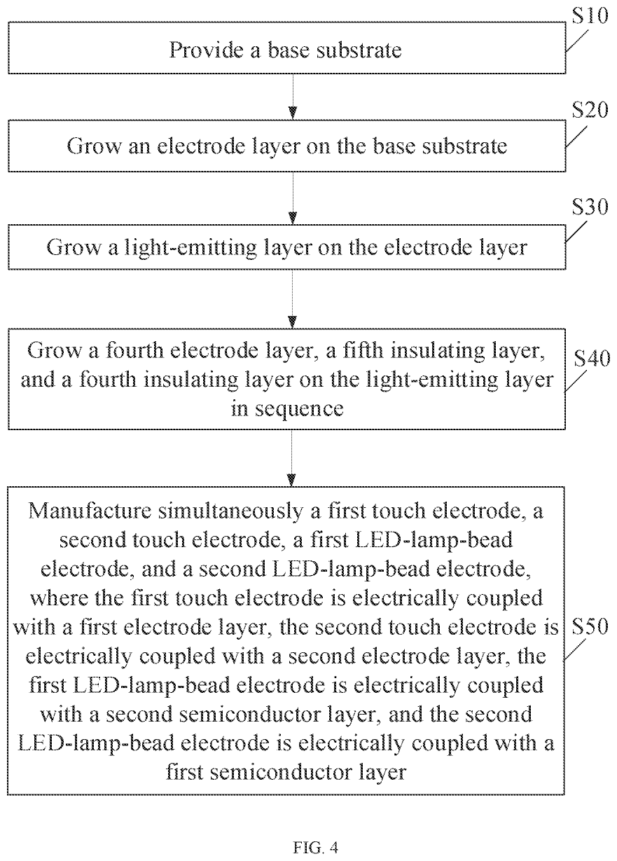

Referring to FIG. 3, FIG. 3 illustrates a top view of an LED touch chip provided in implementations of the disclosure. For convenience of description, in an LED touch chip 100 illustrated in FIG. 3, only the first electrode layer 111, the second electrode layer 113, the first touch electrode 118, and the second touch electrode 119 are illustrated, while the LED-lamp-bead structure 120, the first insulating layer 112, the second insulating layer 114, the third electrode layer 115, the third insulating layer 116, and the fourth insulating layer 117 are omitted.

The LED touch chip 100 illustrated in FIG. 3 further has a touch capacitance region 130. The touch capacitance region 130 refers to an overlapped region of the first electrode layer 111 and the second electrode layer 113. The first touch electrode 118 and the second touch electrode 119 are respectively disposed on opposite sides of the touch capacitance region 130. The first electrode layer 111 is disposed on the base substrate, and coupled with the substrate electrode through the first touch electrode 118. The second electrode layer 113 is disposed on the first insulating layer 112, and coupled with the substrate electrode through the second touch electrode 119. The coupling includes solder-paste bonding. In implementations of the disclosure, each of the first electrode layer 111 and the second electrode layer 113 may be made of indium tin oxide, and has good transparency and conductivity.

Referring to FIG. 4, FIG. 4 is a schematic flowchart illustrating a method for manufacturing an LED touch chip provided in implementations of the disclosure. The method for manufacturing the LED touch chip is used to manufacture the LED touch chip of the implementations illustrated in FIG. 1 and FIG. 2, to improve the sensitivity of the touch screen, reduce the cost of the touch screen, reduce a thickness of an outer frame of the touch screen, and improve an anti-interference performance of the touch screen. As illustrated in FIG. 4, the method for manufacturing the LED touch chip at least includes the following.

At S10, a base substrate 10 is provided.

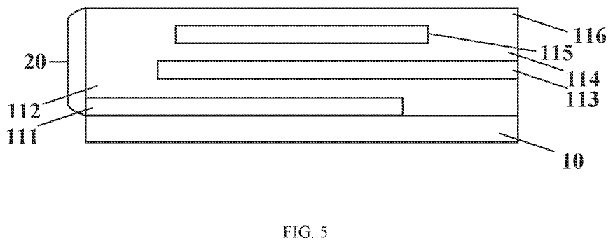

Specifically, referring to FIG. 5, in these implementations, the base substrate 10 is provided to prepare for subsequent growth of a layer structure of the LED touch chip.

At S20, an electrode layer 20 is grown on the base substrate 10.

Specifically, referring to FIG. 5, in implementations of the disclosure, the electrode layer 20 includes a first electrode layer 111, a first insulating layer 112, a second electrode layer 113, a second insulating layer 114, a third electrode layer 115, and a third insulating layer 116.

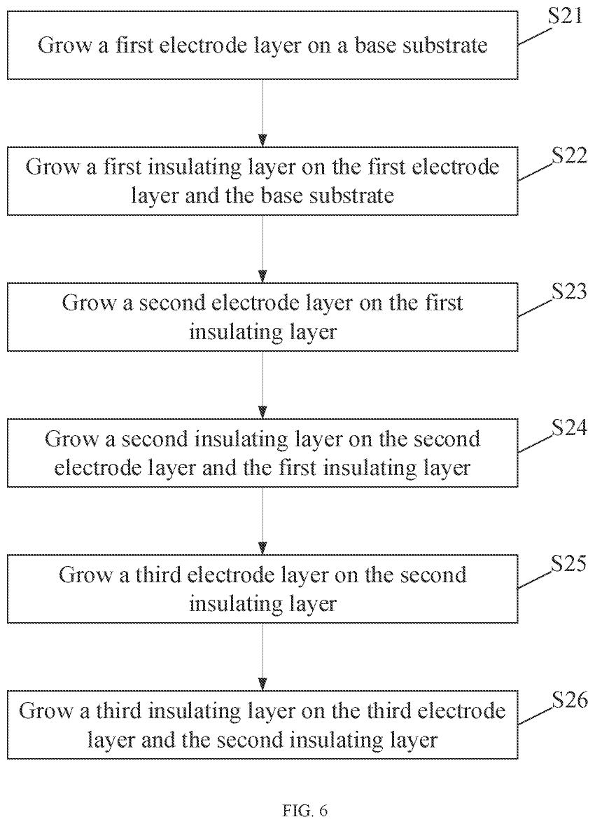

In these implementations, referring to FIG. 6, growing the electrode layer 20 on the base substrate 10 at least includes the following.

At S21, the first electrode layer 111 is grown on the base substrate 10.

The first electrode layer 111 is coupled with the substrate electrode through the first touch electrode 118, where the coupling includes solder-paste bonding.

In implementations of the disclosure, the first electrode layer 111 may be made of indium tin oxide, and has good transparency and conductivity.

At S22, the first insulating layer 112 is grown on the first electrode layer 111 and the base substrate 10.

Part of the first insulating layer 112 is grown on the first electrode layer 111, and the rest of the first insulating layer 112 is grown on the base substrate. In implementations of the disclosure, the first insulating layer 112 may be made of a transparent and non-conductive material, such as resin.

At S23, the second electrode layer 113 is grown on the first insulating layer 112.

The first insulating layer 112 is disposed between the first electrode layer 111 and the second electrode layer 113, to isolate the first electrode layer 111 from the second electrode layer 113, so that the first electrode layer 111 and the second electrode layer 113 are not conductive with each other.

In implementations of the disclosure, the second electrode layer 113 may be made of indium tin oxide, and has good transparency and conductivity.

At S24, the second insulating layer 114 is grown on the second electrode layer 113 and the first insulating layer 112.

Part of the second insulating layer 114 is grown on the second electrode layer 113, and the rest of the second insulating layer 114 is grown on the first insulating layer 112. That is, the second insulating layer 114 is disposed between the second electrode layer 113 and the third electrode layer 115, to isolate the second electrode layer 113 from the third electrode layer 115, so that the second electrode layer 113 and the third electrode layer 115 are not conductive with each other. In implementations of the disclosure, the second insulating layer 114 may be made of a transparent and non-conductive material, such as resin.

At S25, the third electrode layer 115 is grown on the second insulating layer 114.

The third electrode layer 115 is used to shield a signal influence of the second electrode layer 113 on the first semiconductor layer 121 in the LED-lamp-bead structure 120. In implementations of the disclosure, the third electrode layer 115 is in a suspended state, and is not coupled with other electrodes.

At S26, the third insulating layer 116 is grown on the third electrode layer 115 and the second insulating layer 114.

Part of the third insulating layer 116 is grown on the third electrode layer 115, and the rest of the third insulating layer 116 is grown on the second insulating layer 114. That is, the third insulating layer 116 encloses the third electrode layer 115, to isolate the third electrode layer 115 from the first semiconductor layer 121, so that the third electrode layer 115 and the first semiconductor layer 121 are not conductive with each other.

In implementations of the disclosure, the third insulating layer 116 may be made of a transparent and non-conductive material, such as resin.

In implementations of the disclosure, the first electrode layer 111, the second electrode layer 113, and the third electrode layer 115 each are generated through physical vapor deposition (PVD) ion plating, coating, exposure, development, etching, and other processes. The first insulating layer 112, the second insulating layer 114, and the third insulating layer 116 each are generated through chemical vapor deposition (CVD).

At S30, a light-emitting layer 30 is grown on the electrode layer 20.

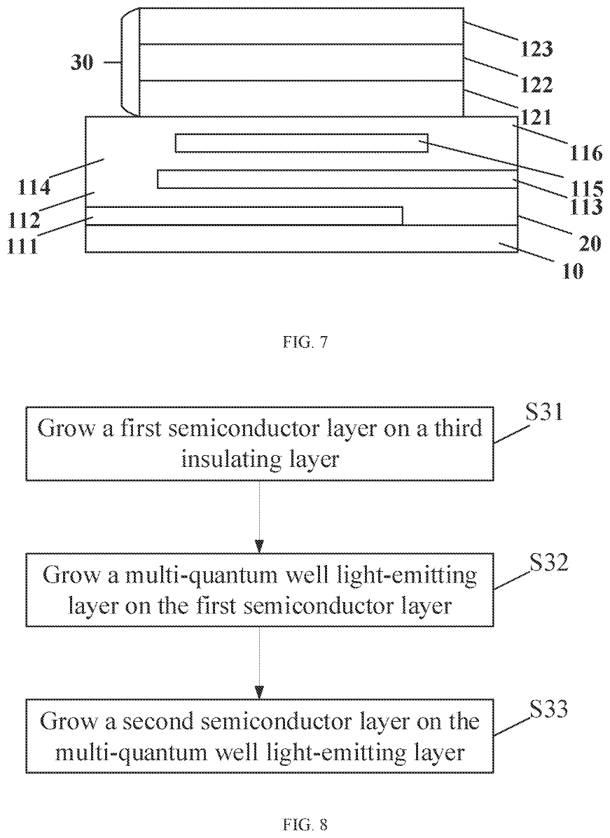

Specifically, referring to FIG. 7, in implementations of the disclosure, the light-emitting layer 30 includes a first semiconductor layer 121, a multi-quantum well light-emitting layer 122, and a second semiconductor 123 which are stacked and grown in sequence.

In these implementations, referring to FIG. 8, growing the light-emitting layer 30 on the electrode layer 20 at least includes the following.

At S31, the semiconductor first layer 121 is grown on the third insulating layer 116.

The first semiconductor layer 121 is configured to provide electrons to recombine with holes provided by the second semiconductor layer 123 to generate photons. In implementations of the disclosure, the first semiconductor layer 121 may be made of an N-type semiconductor material, for example, N-type gallium nitride (GaN). It should be noted that, types of the first semiconductor layer and the second semiconductor layer are not limited in the disclosure. In other implementations, the first semiconductor layer is made of a P-type semiconductor material, and the second semiconductor layer is made of an N-type semiconductor material.

At S32, the multi-quantum well light-emitting layer 122 is grown on the first semiconductor layer 121.

The multi-quantum well light-emitting layer 122 is configured to provide a place where electrons provided by the first semiconductor layer 121 recombine with holes provided by the second semiconductor layer 123 to generate photons.

At S33, the second semiconductor layer 123 is grown on the multi-quantum well light-emitting layer 122.

The second semiconductor layer 123 is configured to provide holes to recombine with electrons provided by the first semiconductor layer 121 to generate photons. In implementations of the disclosure, the second semiconductor layer 123 may be made of a P-type semiconductor material, for example, P-type gallium nitride (GaN).

At S40, a fourth electrode layer 124, a fifth insulating layer 125, and a fourth insulating layer 117 are sequentially grown on the light-emitting layer 30.

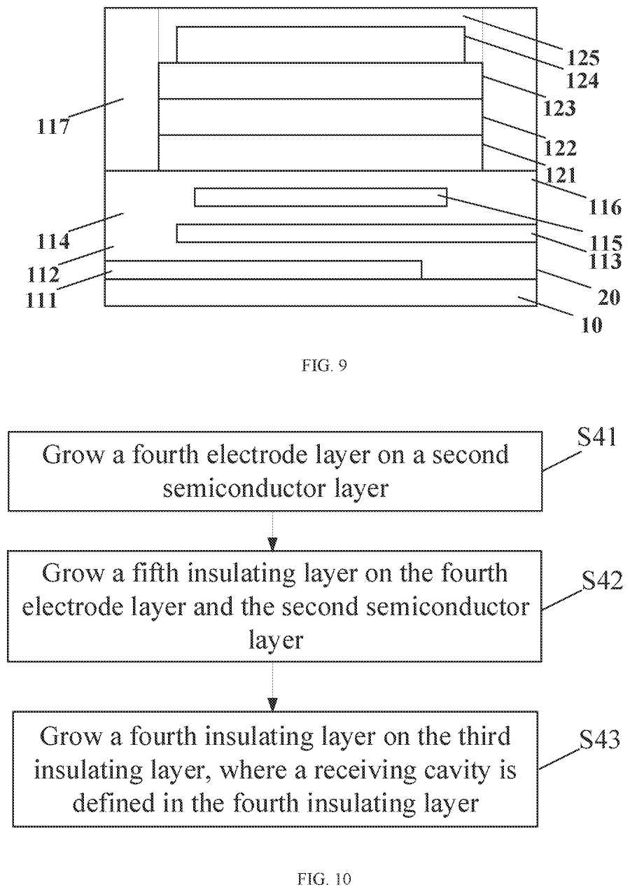

Specifically, referring to FIG. 9 and FIG. 10, in these implementations, sequentially growing the fourth electrode layer 124, the fifth insulating layer 125, and the fourth insulating layer 117 on the light-emitting layer 30 at least includes the following.

At S41, the fourth electrode layer 124 is grown on the second semiconductor layer 123.

The fourth electrode layer 124 is configured to disperse an electric field, so that the electric field of the second semiconductor layer 123 is more uniform and a luminous efficiency is higher.

At S42, the fifth insulating layer 125 is grown on the fourth electrode layer 124 and the second semiconductor layer 123.

Part of the fifth insulating layer 125 is grown on the fourth electrode layer 124, and the rest of the fifth insulating layer 125 is grown on the second semiconductor layer 123, that is, the fifth insulating layer 125 encloses the fourth electrode layer 124. The fifth insulating layer 125 is used to prevent mutual conduction between electrodes. In implementations of the disclosure, the fifth insulating layer 125 may be a DBR.

At S43, the fourth insulating layer 117 is grown on the third insulating layer 116, where the receiving cavity 1102 is defined in the fourth insulating layer 117.

Specifically, the fourth insulating layer 117 is disposed on the third insulating layer 116, and defines the receiving cavity 1102. That is, a periphery of the fourth insulating layer 117 is aligned with a periphery of the third insulating layer 116, and the fourth insulating layer 117 is disposed around the LED-lamp-bead structure 120. In other words, inner walls of the fourth insulating layer 117 and the third insulating layer 116 cooperatively define the receiving cavity 1102, the LED-lamp-bead structure 120 is disposed on the third insulating layer 116, and the fourth insulating layer 117 is disposed around the LED-lamp-bead structure 120. That is, the LED-lamp-bead structure 120 is disposed in the receiving cavity 1102. It can be understood that, in the actual manufacturing process, the fourth insulating layer 117 and the fifth insulating layer 125 may be manufactured at the same time, and manufactured integrally. In implementations of the disclosure, for convenience of description, the fourth insulating layer 117 and the fifth insulating layer 125 are referred to as different insulating layers according to their different positions.

At S50, a first touch electrode 118, a second touch electrode 119, a first LED-lamp-bead electrode 126, and a second LED-lamp-bead electrode 127 are manufactured simultaneously, where the first touch electrode 118 is electrically coupled with the first electrode layer 111, the second touch electrode 119 is electrically coupled with the second electrode layer 113, the first LED-lamp-bead electrode 126 is electrically coupled with the second semiconductor layer 123, and the second LED-lamp-bead electrode 127 is electrically coupled with the first semiconductor layer 121.

Specifically, referring to FIG. 2, the first touch electrode 118 extends through the fourth insulating layer 117, the third insulating layer 116, the second insulating layer 114, and the first insulating layer 112 in sequence, and is electrically coupled with the first electrode layer 111. The first touch electrode 118 is further electrically coupled with the substrate electrode. That is, the first touch electrode 118 is used to electrically connect the first electrode layer 111 and the substrate electrode. In implementations of the disclosure, the first touch electrode 118 may be made of a material with good electrical conductivity. The coupling between the first touch electrode 118 and the substrate electrode includes solder-paste bonding.

The second touch electrode 119 extends through the fourth insulating layer 117, the third insulating layer 116, and the second insulating layer 114 in sequence, and is electrically coupled with the second electrode layer 113. The second touch electrode 119 is further electrically coupled with the substrate electrode. That is, the second touch electrode 119 is used to electrically connect the second electrode layer 113 and the substrate electrode. In implementations of the disclosure, the second touch electrode 119 may be made of a material with good electrical conductivity. The coupling between the second touch electrode 119 and the substrate electrode includes solder-paste bonding.

The first LED-lamp-bead electrode 126 extends through the fifth insulating layer 125 and the fourth electrode layer 124 in sequence, and is electrically coupled with the second semiconductor layer 123. The first LED-lamp-bead electrode 126 is further electrically coupled with the substrate electrode. That is, the first LED-lamp-bead electrode 126 is used to electrically connect the second semiconductor layer 123 and the substrate electrode.

The second LED-lamp-bead electrode 127 extends through the fifth insulating layer 125, the fourth electrode layer 124, the second semiconductor layer 123, and the multi-quantum well light-emitting layer 122 in sequence, and is electrically coupled with the first semiconductor layer 121. The second LED-lamp-bead electrode 127 is further electrically coupled with the substrate electrode. That is, the second LED-lamp-bead electrode 127 is used to electrically connect the first semiconductor layer 121 and the substrate electrode.

Implementations of the disclosure further provide a display device. The display device includes the LED touch chip of the implementations illustrated in FIG. 1 and FIG. 2. The display device further includes a display panel electrically coupled with the LED touch chip. The display device includes, but is not limited to, a Mini LED panel, a Micro LED panel, a mobile phone, a tablet computer, a navigator, a display, and other electronic devices or components with a display function, which is not limited in the disclosure.

It should be understood that, the application of the disclosure is not limited to the foregoing exemplary implementations. Those of ordinary skill in the art can make improvements or equivalent substitutions to the disclosure according to the above descriptions, and all these improvements and equivalent substitutions, however, shall be encompassed within the protection scope of the appended claims of the disclosure.

What is claimed is:

1. A light-emitting diode (LED) touch chip, comprising a base substrate, a touch-screen structure, and an LED-lamp-bead structure, wherein
the touch-screen structure is disposed on the base substrate, and configured to provide a touch function for the LED touch chip;
the LED-lamp-bead structure is disposed in the touch-screen structure, and configured to provide a light-emitting display function; and
the touch-screen structure defines a receiving cavity, and the LED-lamp-bead structure is disposed in the receiving cavity and exposed from the receiving cavity to emit lights.

2. The LED touch chip of claim 1, wherein the touch-screen structure comprises:
a first electrode layer disposed on the base substrate;
a first insulating layer disposed on the first electrode layer and the base substrate;
a second electrode layer disposed on the first insulating layer;
a second insulating layer disposed on the second electrode layer and the first insulating layer;
a third electrode layer disposed on the second insulating layer;
a third insulating layer, wherein part of the third insulating layer is disposed on the third electrode layer, and the rest of the third insulating layer is disposed on the second insulating layer; and
a fourth insulating layer disposed on the third insulating layer, wherein the receiving cavity is defined in the fourth insulating layer.

3. The LED touch chip of claim 2, wherein the touch-screen structure further comprises:
a first touch electrode, extending through the fourth insulating layer, the third insulating layer, the second insulating layer, and the first insulating layer in sequence, and electrically coupled with the first electrode layer; and
a second touch electrode, extending through the fourth insulating layer, the third insulating layer, and the second insulating layer in sequence, and electrically coupled with the second electrode layer.

4. The LED touch chip of claim 2, wherein the LED-lamp-bead structure comprises:
a first semiconductor layer disposed on the third insulating layer;
a multi-quantum well light-emitting layer disposed on the first semiconductor layer;
a second semiconductor layer disposed on the multi-quantum well light-emitting layer;
a fourth electrode layer disposed on the second semiconductor layer; and
a fifth insulating layer disposed on the fourth electrode layer and the second semiconductor layer.

5. The LED touch chip of claim 4, wherein the LED-lamp-bead structure further comprises:
a first LED-lamp-bead electrode, extending through the fifth insulating layer and the fourth electrode layer in sequence, and electrically coupled with the second semiconductor layer; and
a second LED-lamp-bead electrode, spaced apart from the first LED-lamp-bead electrode, extending through the fifth insulating layer, the fourth electrode layer, the second semiconductor layer, and the multi-quantum well light-emitting layer in sequence, and electrically coupled with the first semiconductor layer.

6. The LED touch chip of claim 3, wherein the first electrode layer and the second electrode layer each are made of indium tin oxide; the first insulating layer, the second insulating layer, and the third insulating layer each are made of a transparent and non-conductive material; and the first touch electrode and the second touch electrode each are made of a conductive material.

7. The LED touch chip of claim 2, wherein the third electrode layer is not coupled with other electrodes.

8. The LED touch chip of claim 4, wherein the fourth insulating layer and the fifth insulating layer each are a distributed Bragg reflector (DBR), the first semiconductor layer is made of an N-type semiconductor material, and the second semiconductor layer is made of a P-type semiconductor material.

9. The LED touch chip of claim 4, wherein the fourth insulating layer and the fifth insulating layer each are a distributed Bragg reflector (DBR), the first semiconductor layer is made of a P-type semiconductor material, and the second semiconductor layer is made of an N-type semiconductor material.

10. A display device, comprising:
a display panel; and
a light-emitting diode (LED) touch chip electrically coupled with the display panel, the LED touch chip comprising a base substrate, a touch-screen structure, and an LED-lamp-bead structure, wherein
the touch-screen structure is disposed on the base substrate, and configured to provide a touch function for the LED touch chip;
the LED-lamp-bead structure is disposed in the touch-screen structure, and configured to provide a light-emitting display function; and
the touch-screen structure defines a receiving cavity, and the LED-lamp-bead structure is disposed in the receiving cavity and exposed from the receiving cavity to emit lights.

11. The display device of claim 10, wherein the touch-screen structure comprises:
a first electrode layer disposed on the base substrate;
a first insulating layer disposed on the first electrode layer and the base substrate;
a second electrode layer disposed on the first insulating layer;
a second insulating layer disposed on the second electrode layer and the first insulating layer;
a third electrode layer disposed on the second insulating layer;
a third insulating layer, wherein part of the third insulating layer is disposed on the third electrode layer, and the rest of the third insulating layer is disposed on the second insulating layer; and
a fourth insulating layer disposed on the third insulating layer, wherein the receiving cavity is defined in the fourth insulating layer.

12. The display device of claim 11, wherein the touch-screen structure further comprises:
a first touch electrode, extending through the fourth insulating layer, the third insulating layer, the second insulating layer, and the first insulating layer in sequence, and electrically coupled with the first electrode layer; and
a second touch electrode, extending through the fourth insulating layer, the third insulating layer, and the second insulating layer in sequence, and electrically coupled with the second electrode layer.

13. The display device of claim 11, wherein the LED-lamp-bead structure comprises:
a first semiconductor layer disposed on the third insulating layer;
a multi-quantum well light-emitting layer disposed on the first semiconductor layer;
a second semiconductor layer disposed on the multi-quantum well light-emitting layer;
a fourth electrode layer disposed on the second semiconductor layer; and
a fifth insulating layer disposed on the fourth electrode layer and the second semiconductor layer.

14. The display device of claim 13, wherein the LED-lamp-bead structure further comprises:
a first LED-lamp-bead electrode, extending through the fifth insulating layer and the fourth electrode layer in sequence, and electrically coupled with the second semiconductor layer; and
a second LED-lamp-bead electrode, spaced apart from the first LED-lamp-bead electrode, extending through the fifth insulating layer, the fourth electrode layer, the second semiconductor layer, and the multi-quantum well light-emitting layer in sequence, and electrically coupled with the first semiconductor layer.

15. The display device of claim 11, wherein the third electrode layer is not coupled with other electrodes.

16. A method for manufacturing a light-emitting diode (LED) touch chip, comprising:
providing a base substrate;
growing an electrode layer on the base substrate;
growing a light-emitting layer on the electrode layer;
growing a fourth electrode layer, a fifth insulating layer, and a fourth insulating layer on the light-emitting layer in sequence; and
manufacturing simultaneously a first touch electrode, a second touch electrode, a first LED-lamp-bead electrode, and a second LED-lamp-bead electrode, the first touch electrode being electrically coupled with a first electrode layer, the second touch electrode being electrically coupled with a second electrode layer, the first LED-lamp-bead electrode being electrically coupled with a second semiconductor layer, and the second LED-lamp-bead electrode being electrically coupled with a first semiconductor layer.

17. The method for manufacturing the LED touch chip of claim 16, wherein growing the electrode layer on the base substrate comprises:
growing the first electrode layer on the base substrate;
growing a first insulating layer on the first electrode layer and the base substrate;
growing the second electrode layer on the first insulating layer;
growing a second insulating layer on the second electrode layer and the first insulating layer;
growing a third electrode layer on the second insulating layer; and
growing a third insulating layer on the third electrode layer and the second insulating layer.

18. The method for manufacturing the LED touch chip of claim 17, wherein growing the light-emitting layer on the electrode layer comprises:
growing the first semiconductor layer on the third insulating layer;
growing a multi-quantum well light-emitting layer on the first semiconductor layer; and
growing the second semiconductor layer on the multi-quantum well light-emitting layer.

19. The method for manufacturing the LED touch chip of claim 18, wherein growing the fourth electrode layer, the fifth insulating layer, and the fourth insulating layer on the light-emitting layer in sequence comprises:
growing the fourth electrode layer on the second semiconductor layer;
growing the fifth insulating layer on the fourth electrode layer and the second semiconductor layer; and
growing the fourth insulating layer on the third insulating layer, wherein inner walls of the fourth insulating layer and the third insulating layer cooperatively define a receiving cavity, wherein the light-emitting layer, the fourth electrode layer, the fifth insulating layer, the first LED-lamp-bead electrode, and the second LED-lamp-bead electrode are disposed in the receiving cavity.

20. The method for manufacturing the LED touch chip of claim 17, wherein the first electrode layer, the second electrode layer, and the third electrode layer each are generated through physical vapor deposition (PVD) ion plating, and the first insulating layer, the second insulating layer, and the third insulating layer each are generated through chemical vapor deposition (CVD).
